(19) United States
(12) Patent Application Publication
(10) Pub. No.: US 2020/0157680 A1
(43) Pub. Date: May 21, 2020

(54) PEALD PROCESSES USING RUTHENIUM PRECURSOR

(71) Applicant: ENTEGRIS, INC., Billerica, MA (US)

(72) Inventors: Philip S.H. CHEN, Bethel, CT (US); Bryan C. HENDRIX, Danbury, CT (US); Thomas H. BAUM, New Fairfield, CT (US); Eric CONDO, Shelton, CT (US)

(21) Appl. No.: 16/675,845

(22) Filed: Nov. 6, 2019

Related U.S. Application Data
(60) Provisional application No. 62/767,967, filed on Nov. 15, 2018.

(51) Int. Cl. C23C 16/455; C23C 16/06; C07F 15/00

(52) U.S. Cl. CPC C23C 16/45536; C07F 15/0046; C23C 16/06

(57) ABSTRACT

Plasma enhanced atomic layer deposition (PEALD) processes which use a ruthenium precursor of formula R^{A}R^{B}Ru(0), wherein R^{A} is an aryl group-containing ligand, and R^{B} is a diene group-containing ligand, along with a reducing plasma applied at greater than 200 W are described. Use of the R^{A}R^{B}Ru(0) ruthenium precursors in PEALD with +200 W reducing plasma such as ammonia plasma, can provide very good rates of deposition of Ru, have lower carbon and less resistivity, and provide very dense Ru films. The method can be used to form well-formed Ru film with high conformality on integrated circuits and other microelectronic devices.

### FIELD OF THE INVENTION

The invention relates to plasma enhanced atomic layer deposition methods using a ruthenium-containing precursor and reducing plasma, and microelectronic articles made therefrom.

### BACKGROUND

Ruthenium (Ru) has been used as a material in the fabrication of various microelectronic articles, such as in industrial semiconductor manufacturing. Ruthenium can provide various desirable properties to these types of articles, such as high thermal stability/melting point, low resistivity, etchability, resistance to oxidation, and copper seed enhancement. Ru is considered a possible gate electrode material for complementary metal-oxide-semiconductors (CMOS) as well as capacitors for random-access memory applications such as ferroelectric RAM (FRAM) and dynamic random-access memory (DRAM) applications.

Various depositions techniques have been used to deposit materials, such as Ru, during the formation microelectronic articles that are useful for their function. These deposition processes are often used to form a thin film of the material on a portion of the microelectronic substrate. Exemplary techniques include Chemical Vapor Deposition (CVD), Atomic Layer Deposition (ALD), evaporation deposition, and Molecular Beam Epitaxy (MBE).

In a typical CVD process, metals such as ruthenium are complexed in the form of volatile metal precursors which react or decompose on the substrate surface to form a deposit of the metal, and generally resulting in the formation of volatile by-products which are removed from the deposition chamber using gas flow.

In ALD, a more specific type of CVD, a ruthenium thin film is formed by decomposing a reactant by a chemical exchange as promoted by supplying reactant materials in separate, intermittent steps. By using this technique, ALD can provide better step coverage method than by a CVD method. Furthermore, ALD can be carried out at a lower temperature than CVD, which in turn can provide processing benefits as well as advantages for thin film formation.

Plasma-Enhanced Atomic Layer Deposition (PEALD) utilizes steps that provide reactant in radical (plasma) form to the substrate surface to promote layer growth. Generally, a PEALD system includes a plasma source with RF power supply, and optional gas flow regulators. A PEALD reaction may also be configured differently than a CVD reactor to ensure uniform exposure of the substrate to the radical flux. However, the PEALD process can be beneficial through use of lower temperature deposition, more complete reaction of depositing material and (precursor) ligand removal, and reduced nucleation and purge times.

Ru thin films formed from precursors and deposition processes such as CVD, ALD, and PEALD are desirable as an adhesion layer for a copper diffusion barrier (TiN/TaN) layer, a diffusion barrier layer, and a seed layer for Cu electrochemical plating (ECP). However, the deposition of Ru on substrates using Ru precursors and CVD, ALD, and PEALD deposition can be a technically challenging process and also lead to undesired results. Ruthenium precursors including those using carbonyl, diketonate, and other organometallic chemistries can require an oxidizing compound for successful deposition of Ru on the target substrate. For example, the use of oxidizing compounds can be counterproductive especially when they change the properties or damage other materials of other materials of the substrate. The presence of an oxidant can lead to oxidation damage of an under-laying nitride film leaving it as a less conductive interface.

Despite many superior aspects of CVD, ALD, and PEALD methods generally, prior techniques have not been successful at depositing ruthenium on certain underlying layers, such as copper layers. Thus, there is a need in the art for depositing ruthenium on thin metals layers to achieve the benefits of ruthenium without the deleterious effects described above.

### SUMMARY

The invention relates to methods and compositions for depositing ruthenium on a substrate material in a Plasma-Enhanced Atomic Layer Deposition (PEALD) process. PEALD methods of the invention use certain ruthenium precursor chemistries in combination with a reducing gas under high power conditions to provide selective and high quality ruthenium deposition as well as desirable processing conditions. Also, PEALD methods of the invention at the same time minimize or eliminate damage to substrate materials that would otherwise occur through undesirable oxidation. The process and composition of the disclosure can be used in the fabrication of microelectronic articles like integrated circuits (ICs), such as in industrial semiconductor manufacturing, to provide barrier material or liner between a low k dielectric material and a conductive interconnect material.

In one embodiment, the invention provides a method for depositing ruthenium in a plasma enhanced atomic layer deposition (PEALD) process which includes the steps of (a) providing a ruthenium precursor of the Formula I: R^{A}R^{B}Ru(0), wherein R^{a} is an aryl group-containing ligand, and R^{b} is a diene group-containing ligand, to a substrate surface, and a step of (b) providing a reducing plasma to the substrate surface using a power of greater than 200 W, wherein ruthenium is deposited on the substrate.

In the ruthenium precursor R^{a} is preferably a mono-, di-, or tri-alkylbenzene (e.g., cymene), and R^{b} is preferably a cyclic unconjugated diene, such as cyclohexadiene or an alkylcyclohexadiene. The ruthenium precursor of the formula R^{A}R^{B}Ru(0) can be present in an organic solvent which can facilitate the PEALD process to form a ruthenium-containing layer on a conductive substrate.

The combination of the ruthenium precursor of the formula R^{A}R^{B}Ru(0) using in PEALD with reducing plasma such as ammonia plasma, can provide very good rates of deposition of Ru, thereby improving the deposition process. Beneficially, the films formed at these higher plasma powers have lower carbon and less resistivity than those formed at lower plasma powers. The PEALD process was also able to form well-formed thin films with high conformality on low aspect structures. Further, the PEALD process allowed the formation of dense Ru films, having up to 100% density.

In further aspects, higher temperatures could be used to provide better nucleation and lower resistivity on Si/O-containing substrates. Beneficially, the method using the ruthenium-containing precursor of the current disclosure along with a reducing gas can result in very good nucleation of a substrate with formation of high quality ruthenium films, with minimal carbon left on the substrate following deposition.

The PEALD deposition process using the ruthenium precursor, and reducing plasma at high power, can provide Ru films on substrate materials such as copper (Cu), titanium (Ti), cobalt (Co), aluminum (Al), nickel (Ni), and tungsten (W), or on SiO₂, SiN, SiOC, SiOCN, and SiON, or both (a) and (b), with desired levels of thickness, density, and resistivity.

In embodiments, the substrate includes an integrated circuit, which can be partly formed from a material that is non-conductive or less conductive than the conductive feature, such as a di-electric. In the integrated circuit the conductive feature (e.g., copper-containing) can be an interconnect, such as a line or a via, that functions to conduct electric current among and between various electronic features of the integrated circuit. The deposited ruthenium can be in the form as a single layer functioning as a liner or a barrier layer between a conductive interconnect material and a low k dielectric material. Therefore, in another aspect, the invention relates to an integrated circuit prepared using the high power PEALD method using the ruthenium precursor of the formula R^{A}R^{B}Ru(0) along with reducing plasma such as ammonia or hydrogen plasma.

In other embodiments, the invention provides a system for PEALD for depositing ruthenium on a substrate which includes a ruthenium source comprising a ruthenium precursor of the formula R^{A}R^{B}Ru(0), wherein R^{A} is an aryl group-containing ligand, and R^{B} is a diene group-containing ligand; and reducing gas source, and a power source capable of generating plasma from the reducing gas. The system can be in the form of a PEALD apparatus which can include features, such as a deposition chamber, a substrate support, and one or more gas source(s), etc.

### BRIEF DESCRIPTION OF THE FIGURES

FIG. 1 is a graph showing increases in Ru coating thickness (Å) as measured by X ray fluorescence spectroscopy (XRF) on Cu, TaN, TiN, WCN, WN, and SiO₂ after numbers of deposition cycles at 250° C.

FIG. 2 is a graph showing increases in Ru coating thickness (Å) as measured by X ray fluorescence spectroscopy (XRF) on Cu, TaN, TiN, WCN, WN, and SiO₂ after numbers of deposition cycles at 280° C.

FIG. 3 is a graph showing resistivity of Ru coating based on thickness (Å) on WCN, WN, and SiO₂ substrates, demonstrating low electrical resistivity at Ru film thickness<5 nm.

FIG. 4A is a scanning electron micrograph (SEM) image of a dense as dep Ru coating on SiO₂ formed using higher power Ru deposition process.

FIG. 4B is a scanning electron micrograph (SEM) image of a dense RTH (rapid thermal annealing with hydrogen) annealed Ru coating on SiO₂ formed using higher power Ru deposition process.

FIG. 4C is a scanning electron micrograph (SEM) image of a dense as dep Ru coating on WCN formed using higher power Ru deposition process.

FIG. 4D is a scanning electron micrograph (SEM) image of a dense as dep RTH annealed Ru coating on WCN formed using higher power Ru deposition process.

FIG. 5 is an X-ray diffraction (XRD) graph of a Ru coating, as dep and post 400° C. RTH anneal.

FIG. 6 is a graph showing increases in Ru coating thickness (Å) as measured by X ray fluorescence spectroscopy (XRF) on Cu, TaN, TiN, WCN, WN, and SiO₂ after numbers of deposition cycles.

FIG. 7 is a graph showing Ru thin films deposited at 280° C. with H₂ PEALD have lower resistivity than those deposited with O₂ thermal CVD.

FIG. 8 shows that Ru films deposited on WCN/WN with H₂ plasma have lower resistivity than those deposited with NH₃ plasma.

FIG. 9 is a graph showing increases in Ru coating thickness (Å) as measured by X ray fluorescence spectroscopy (XRF) on Cu, TaN, TiN, WCN, WN, and SiO₂ after numbers of deposition cycles (comparative).

FIG. 10 is a graph showing broader XRD peaks with 200 W NH₃ plasma.

FIG. 11 is a schema of a PEALD system.

FIG. 12A is a scanning electron micrograph (SEM) image of a porous as-dep Ru coating on SiO₂ formed using 200 W Ru deposition process.

FIG. 12B is a scanning electron micrograph (SEM) image of a porous RTH annealed Ru coating on SiO₂ formed using 200 W Ru deposition process.

FIG. 12C is a scanning electron micrograph (SEM) top-down image of a porous RTH annealed Ru coating on SiO₂ formed using 200 W Ru deposition process showing severe cracks of the Ru film due to shrinkage from annealing.

### DETAILED DESCRIPTION

The present disclosure relates to plasma-enhanced atomic layer deposition (PEALD) methods using ruthenium precursors of the formula R^{A}R^{B}Ru(0) which are configured for use along with a reducing gas such as hydrogen. Disclosed herein are also PEALD systems that include sources for the ruthenium precursor and reducing gas, and optionally oxygen, configured for use in a deposition process. The present disclosure also relates to methods for forming a ruthenium-containing layer on a conductive surface, and substrates formed therefrom. The present disclosure also relates to methods for forming integrated circuits which use the precursors of the disclosure, as well as the integrated circuits that are formed as a result of the process.

Ruthenium-containing precursors of the disclosure include compounds of the Formula I R^{A}R^{B}Ru(0), wherein R^{A} is benzene or an aryl group-containing ligand, and R^{B} is a diene group-containing ligand. As used herein, an “aryl group-containing ligand” includes at least one aromatic ring with one or more hydrocarbon substituents attached to the aromatic ring. For example, the aryl group-containing ligand can be a mono-, di-, or tri-alkylbenzene, or a fused ring structure such as indane or tetrahydronaphthalene (benzocyclohexane, tetralin).

As used herein a “diene group-containing ligand” is a compound including at least two carbon-carbon double bonds separated by at least one carbon-carbon single bond, and can include conjugated dienes and unconjugated dienes, with conjugated dienes being preferred. Diene group-containing ligands can optionally include more than two carbon-carbon double bonds, such as trienes. Diene group-containing ligands include linear and cyclic compounds, with cyclic compounds being preferred. Cyclic diene group-containing ligands can have a single ring structure, such as cyclohexadiene, cyclohexadiene, or alkylated derivatives thereof, or can have a fused cyclic ring structure, such as hexahydronaphthalene, thetrahydroindene, dicyclopentadiene, or norbornadiene.

For example, R^{A} can be selected from the group consisting of toluene, xylene, ethylbenzene, cumene, and cymene. In embodiments, R^{B} can be a cyclic or linear unconjugated diene. Preferably, R^{B} is cyclohexadiene or an alkylcyclohexadiene. For example, R^{B} can be selected from the group consisting of cyclohexadiene, methylcyclohexadiene, ethylcyclohexadiene, and propylcyclohexadiene.

Exemplary ruthenium-containing precursors of the disclosure include compounds of the formula II:

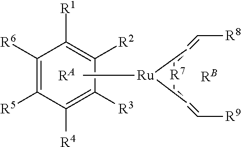

wherein one or more or R¹-R⁶ are selected from H and C1-C6 alkyl, R⁷ is 0 (covalent bond) or a divalent alkene group of 1-4 carbon atoms, and R⁸ and R⁹ form one or more ring structures or are selected from H and C1-C6 alkyl. Preferably, one, two, or three of R³-R⁸ are selected from C1-C6 alkyl, or more preferably C1-C3 alkyl, with the remaining R¹-R⁶ being H. Preferably, R⁷ is 0 (covalent bond), and R⁸ and R⁹ form one or more ring structures.

In some embodiments, the ruthenium precursor of the formula R^{A}R^{B}Ru(0) does not include any heteroatoms (i.e., an atom other than carbon or hydrogen). For example, R^{A} and R^{B} can consist of carbon and hydrogen. Compounds of formula R^{A}R^{B}Ru(0) can also be described in terms of their degree of unsaturation, their total carbon atom content, their total hydrogen content, or combinations thereof.

For example, the ruthenium precursor of the formula R^{A}R^{B}Ru(0) can have a total carbon atom amount in the range of (a1) 12 to 20, in the range of (a2) 14 to 18, or in the range of (a3) 15 to 17. A preferred ruthenium precursor has a total carbon atom amount of (a4) 16. The ruthenium precursor of the formula R^{A}R^{B}Ru(0) can also have a total hydrogen atom amount in the range of (b1) 16 to 28, in the range of (b2) 19 to 25, or in the range of (b3) 20-24. A preferred ruthenium precursor has a total hydrogen atom amount of 22. The ruthenium precursor can have combined carbon and hydrogen amounts of (a1) and (b1), (a2) and (b2), or (a3) and (b3).

Exemplary compounds of formula R^{A}R^{B}Ru(0) include, but are not limited to, (cymene)(1,3-cyclohexadiene)Ru(0), (cymene)(1,4-cyclohexadiene)Ru(0), (cymene)(1-methylcyclohexa-1,3-diene)Ru(0), (cymene)(2-methylcyclohexa-1,3-diene)Ru(0), (cymene)(3-methylcyclohexa-1,3-diene)Ru(0), (cymene)(4-methylcyclohexa-1,3-diene)Ru(0), (cymene)(5-methylcyclohexa-1,3-diene)Ru(0), (cymene)(6-methylcyclohexa-1,3-diene)Ru(0), (cymene)(1-methylcyclohexa-1,4-diene)Ru(0), (cymene)(2-methylcyclohexa-1,4-diene)Ru(0), (cymene)(3-methylcyclohexa-1,4-diene)Ru(0), (cymene)(4-methylcyclohexa-1,4-diene)Ru(0), (cymene)(5-methylcyclohexa-1,4-diene)Ru(0), and (cymene)(6-methylcyclohexa-1,4-diene)Ru(0). Cymene is also known as 1-Methyl-4-(propan-2-yl)benzene or 1-isopropyl-4-methylbenzene.

Exemplary compounds of formula R^{A}R^{B}Ru(0) also include, but are not limited to, (benzene)(1,3-cyclohexadiene)Ru(0), (toluene)(1,3-cyclohexadiene)Ru(0), (ethylbenzene)(1,3-cyclohexadiene)Ru(0), (1,2-xylene)(1,3-cyclohexadiene)Ru(0), (1,3-xylene)(1,3-cyclohexadiene)Ru(0), (1,4-xylene)(1,3-cyclohexadiene)Ru(0), (p-cymene)(1,3-cyclohexadiene)Ru(0), (o-cymene)(1,3-cyclohexadiene)Ru(0), (m-cymene)(1,3-cyclohexadiene)Ru(0), (cumene)(1,3-cyclohexadiene)Ru(0), (n-propylbenzene)(1,3-cyclohexadiene)Ru(0), (m-ethyltoluene)(1,3-cyclohexadiene)Ru(0), (p-ethyltoluene)(1,3-cyclohexadiene)Ru(0), (o-ethyltoluene)(1,3-cyclohexadiene)Ru(0), (1,3,5-trimethylbenzene)(1,3-cyclohexadiene)Ru(0), (1,2,3-trimethylbenzene)(1,3-cyclohexadiene)Ru(0), (tert-butylbenzene)(1,3-cyclohexadiene)Ru(0), (isobutylbenzene)(1,3-cyclohexadiene)Ru(0), (sec-butylbenzene)(1,3-cyclohexadiene)Ru(0), (indane)(1,3-cyclohexadiene)Ru(0), (1,2-diethylbenzene)(1,3-cyclohexadiene)Ru(0), (1,3-diethylbenzene)(1,3-cyclohexadiene)Ru(0), (1,4-diethylbenzene)(1,3-cyclohexadiene)Ru(0), (1-methyl-4-propylbenzene)(1,3-cyclohexadiene)Ru(0), and (1,4-dimethyl-2-ethylbenzene)(1,3-cyclohexadiene)Ru(0).

Ruthenium-containing precursors of Formula I R^{A}R^{B}Ru(0) can also be described with reference to the melting and/or boiling point of the compound. In embodiments, the ruthenium-containing precursor is a liquid at room temperature (25° C.). For example, the ruthenium-containing precursor may also have a boiling point in a temperature range of about 100° C. to about 175° C., or more specifically about 120° C. to about 150° C.

If the ruthenium-containing precursor of Formula I is in the form of a liquid at room temperature (25° C.), it can be described in terms of its vapor pressure. The vapor pressure of a liquid is the equilibrium pressure of a vapor above its liquid. The pressure of the vapor results from evaporation of the liquid as measured in a closed container at a certain temperature. For example, the precursor may have a vapor pressure at 100° C. of at least about 0.01 Torr, or at least about 0.05 Torr, such as in the range of about 0.05 Torr to about 0.50 Torr, or in the range of about 0.1 Torr to about 0.30 Torr.

Ruthenium-containing precursors of Formula I R^{A}R^{B}Ru(0) can be made by reacting a ruthenium-containing reactant, such as a ruthenium salt hydrate, with a first hydrocarbon-containing ligand (R^{A}), forming an intermediate, and then reacting the intermediate with a second hydrocarbon-containing ligand (R^{B}) to form the final product.

For example, Eom, T.-K., et al. (Electrochemical and Solid State Letters, 12:D85-D88, 2009) prepared (6-1-isopropyl-4-methylbenzene)-(4-cyclohexa-1,3-diene)Ru(0) (IMBCHRu) by preparing an ethanol solution of ruthenium trichloride hydrate and a-terpene, refluxing for 5 hours, to form a microcrystalline product of m-chloro-bis(chloro(1-isopropyl-4-methylbenzene)ruthenium(II)), which was then dried and then added to a solution of ethanol with Na2CO3, and 1,3-cyclohexadiene, and then refluxed for 4.5 hours.

The disclosure provides PEALD methods for forming a ruthenium-containing layer on a substrate material. The PEALD method involves providing a substrate, such as one comprising a conductive, a semi-conductive, or non-conductive material, or combinations thereof, and using a ruthenium-containing precursor of the disclosure in a chemical vapor deposition process to form a ruthenium-containing layer on the conductive feature, wherein the method includes a step of providing reducing plasma to the substrate surface using a power of greater than 200 W.

The conductive, a semi-conductive, or non-conductive material, or combinations thereof, can be in the form of one or more features of an integrated circuit. An integrated circuit generally includes one or more materials that are dielectics that are non-conductive or less conductive than the conductive feature. In the integrated circuit the conductive feature (e.g., copper-containing) can be an interconnect, such as a line or a via, that function to conduct electric current among and between various electronic features of the integrated circuit. The dielectric of the integrated circuit can include a silicon-containing material, and oxygen-containing material, or both, such as silicon dioxide.

The ruthenium-containing layer can be in the form of a thin film which can be formed using a plasma-enhanced atomic layer deposition (PEALD) method that includes a step of providing reducing plasma to the substrate surface using a power of greater than 200 W, as exemplified by the current disclosure. Method of the disclosure may alternatively be referred to as plasma-enhanced chemical vapor deposition (PECVD). PEALD can be performed using a system including a deposition chamber and a heating feature which heats the reactant materials to a desired temperature during the process. The system can also include a vacuum pump to provide a sub-atmospheric pressure in the deposition chamber. The system can also include sources for the ruthenium precursor, the reducing plasma, and an inert gas, and conduits and regulators that can provide and modulate the flow of these materials into the deposition chamber.

The PEALD process can include multiple cycles, with each cycle including multiple steps. Prior to initiating a first cycle, the substrate can optionally be pretreated to equilibrate the substrate, to prime the substrate, or both, for the deposition process. For example, the substrate can be pretreated by heating the substrate, or pretreating with the reducing plasma. Pretreatment may prime the surface of the substrate to facilitate deposition of the ruthenium during a deposition cycle. Once the any optional pretreatment is performed a deposition cycle can begin, with a first step one cycle being a pulse of the ruthenium precursor into the deposition chamber. During this step, the ruthenium precursor has a residence period in the deposition chamber in which a monolayer of precursor is adsorbed on the substrate surface. An inert gas such as argon can be introduced along with the ruthenium precursor during this deposition step. After the precursor adsorption step, a step of purging can be performed which can remove and any unreacted precursor material from the deposition chamber. The purging step following deposition can be carried out using an inert gas, and may be the same inert gas used during the deposition step. After the purging, a step of treating the substrate with reducing plasma using a power of greater than 200 W is performed. For example, a reducing gas such as ammonia or hydrogen is delivered to the deposition chamber under high power conditions, wherein a reducing plasma is generated, which reacts with the ruthenium precursor adsorbed in the first step of the cycle to deposit Ru on the substrate surface. After the plasma treatment step, a step of purging the deposition chamber can be performed which can remove the decomposed materials of the precursor and reducing material (e.g., gas from plasma formed during the plasma treatment step) from the deposition chamber. Accordingly, a cycle of the PEALD process as described herein can include at least four steps, or can consist of four steps, with a first step of Ru precursor adsorption, a first purging step, a reducing plasma treatment step, and a second purging step (e.g., Ru adsorption-1 purge-plasma-2 purge; A-B-C-D; etc.).

During an entire cycle, an inert gas or inert gas mixture can be continuously flowed into the chamber. Examples of inert gasses are helium, argon, krypton, neon, and xenon. The Ru deposition and reducing plasma treatment steps can be conducted during the continuous flow of inert gas into the chamber, therefore steps of the cycle can be established by regulating the flow of Ru precursor and reducing gas into the deposition chamber. Exemplary flow rates of the inert gas throughout the entire cycles about 500 sccm or greater, such as in the range of about 500 to about 700 sccm. For example, during continuous flow of an inert gas, delivery of the Ru precursor to the deposition chamber is started, continued for a period of time, and then stopped, and this defines the Ru precursor adsorption step. The continuous flow of inert gas serves as a purge after flow of the Ru precursor is stopped. The period of inert gas flow between which the flow of the Ru precursor is stopped and the flow of reducing gas is started defines the first purge step. Accordingly, during continuous flow of the inert gas, delivery of the reducing gas to the deposition chamber is started, continued for a period of time, and then stopped, which defines the reducing plasma treatment step. The continuous flow of inert gas serves as a purge after flow of the reducing gas is stopped. After the second purge step, a new cycle can begin.

Optionally, prior to the first cycle, the substrate can be pretreated, such as to equilibrate or prime the substrate for Ru deposition. A pretreatment can use an inert gas, a reducing gas or plasma, or combinations thereof. For example, prior to the step of deposition of the ruthenium-containing precursor on the substrate, the substrate can optionally be pretreated, such as pretreated with a reducing gas or plasma. In embodiments, methods of the disclosure can include a step of pre-treating the substrate with a reducing gas or reducing plasma, or reducing gas or reducing plasma mixture, that includes a reducing gas such as H₂, NH₃, hydrazine, or a mixture thereof, or plasma formed from any one or more of these gasses, prior to using the ruthenium-containing precursor in the deposition process. Optional pretreatment with reducing gas or plasma can be carried out using temperature, power, pressure, period, and flow rate conditions described herein for reducing gas/plasma treatment during a deposition cycle.

In a first step of a precursor adsorption cycle, the ruthenium-containing precursor of the disclosure can be introduced into a deposition chamber in vapor form, wherein the chamber in the substrate. In some modes of practice, the ruthenium-containing precursor in vapor form can be generated by vaporizing a composition in liquid form that includes the precursor. Vaporization of the precursor can be achieved by a process such as distillation, vaporization, or bubbling an inert gas such as argon or helium through the liquid composition, the (e.g. Ar, etc.), wherein the ruthenium-containing precursor, and any optional inert gas, is introduced into the deposition chamber. In some modes of practice the ruthenium precursor is provided in a gas stream flow comprising an inert gas selected from helium, argon, krypton, neon, and xenon.

Optionally, and in some embodiments, if the ruthenium-containing precursor is in solid or semisolid form, it can be heated to a temperature that melts the precursor so it is in liquid form and generates a vapor pressure adequate for use in the deposition process. For example, the ruthenium-containing precursor can be heated in a container to a temperature of greater than 25° C., such as a temperature in the range of 25° C. to about 150° C., a temperature in the range of about 30° C. to about 125° C., or a temperature in the range of about 80 to about 120° C. The ruthenium-containing precursor can be heated prior to or during a step of vaporizing the ruthenium-containing precursor during introduction into the deposition chamber. Pre-heating the ruthenium-containing precursor can optionally be performed even if the precursor is in liquid form (e.g., at about 25° C.).

Techniques to introduce the ruthenium precursor also include direct liquid injection where liquid precursors or solid precursors dissolved in a solvent are injected and vaporized using injectors to provide the chemical precursor in vapor form in a deposition chamber. Deposition apparatus can also include features such as a sonicator which can be used to help generate aerosol ultrasonically, wherein the aerosol includes the chemical precursor. The PEALD apparatus can also include a power source to heat the chamber which can in turn heats the precursor and substrate, or a filament that can heat the chemical precursor and cause it volatilization and/or decomposition.

The ruthenium precursor can be provided to the deposition chamber in a gas stream flow, with an exemplary flow rate being in the range of about 250 to about 425 sccm (standard cubic centimeters per minute). In more specific aspects the flow rate is in the range of about 300 to about 375 sccm, or in the range of about 320 to about 350 sccm. Deposition of the ruthenium precursor can be carried out at a desired pressure in the deposition chamber, with an exemplary pressure being in the range of about 1 to about 5 Torr. In more specific aspects the pressure is in the range of about 2 to about 4 Torr, or in the range of about 2.5 to about 3.5 Torr. In exemplary aspects, the deposition chamber temperature is less than about 500° C., less than about 450° C., and preferably in the range of about 150° C. to about 450° C., or about 200 to about 350° C. during the Ru deposition step.

Further, adsorption of the ruthenium precursor can be carried out at a desired period of time during the adsorption step of the cycle, with an exemplary period being in the range of about 0.5 to about 25 seconds. In more specific aspects the deposition period is in the range of about 1 to about 15 seconds, or in the range of about 2 to about 12 seconds. During the adsorption period the ruthenium precursor R^{A}R^{B}Ru(0) thereby adsorb on the substrate surface to produce the desired layer. The materials that are not adsorbed to form the Ru layer can be removed in a subsequent purge step.

In a second step of a cycle, a gas is flowed into the deposition chamber to remove by-products of the ruthenium precursor, and any ruthenium precursor that did not adsorb to the substrate during the first step. The gas can be helium, argon, krypton, neon, and xenon, which may be also used in the first step of deposition. In some modes of practice, if the first step includes flowing the Ru precursor and an inert gas into the deposition chamber, the second step can begin when the flow of Ru precursor is stopped while continuing flow of the inert gas. Optionally, during the purge step the flow of inert gas can be increased to more rapidly purge the by-products of the ruthenium precursor from the chamber. Exemplary flow rates of the inert gas during the purge step are about 500 sccm or greater, about 550 sccm or greater, such as in the range of about 500 to about 700 sccm, or in the range of about 575 to about 650 sccm. After a desired period of time the purging step can cease, and a reducing gas can be introduced into the deposition chamber to begin the reducing plasma treatment step.

After purging, a step of treating the adsorbed precursor with a reducing plasma can commence, which can be a third step in the cycle. For example, a reducing gas can be flowed into the deposition chamber while at the same time providing energy to the deposition chamber to generate reducing plasma from the reducing gas that is ionized. Exemplary gas sources that can provide reducing plasma include ammonia, hydrogen, and hydrazine. Mixtures of reducing gasses can be used.

An energy sources such as radio frequency (RF) sources can provide power to the deposition chamber sufficient to ionize the reducing gas, or reducing gas mixture, that is introduced and form reducing gas plasma. In the step of treating with reducing plasma, the power applied is greater than 200 W, and in embodiments greater than about 250 W, greater than about 275 W, greater than about 300 W, greater than about 325 W, or even greater than about 350 W. For example, the power applied can be in the range of about 250 to about 500 W, in the range of about 300 to about 475 W, in the range of about 350 to about 450 W, or in the range of about 375 to about 425 W. During the step of reducing plasma treatment, the power applied can optionally vary, such as by increasing the power over the treatment period.

The reducing plasma can be generated by flowing a reducing gas into the deposition chamber when then becomes ionized. Exemplary flow rates of the reducing gas at least 50 sccm, at least about 100 sccm, at least about 150 sccm, or at least about 175 sccm. In more specific aspects the flow rate of the reducing gas is in the range of about 100 to about 400 sccm, in the range of about 150 to about 300 sccm, or in the range of about 175 to about 275 sccm. The amount of reducing gas flowed into the chamber may optionally be expressed in terms of the amount of reducing gas to total gas (reducing gas and inert gas) flowed into the chamber during the reducing plasma treatment step. For example, the amount of reducing gas can be in the range of about 10% to about 50%, about 15% to about 40%, or about 20% to about 35% of the total amount of gas flowed into the chamber during the reducing plasma treatment step.

Reducing plasma treatment can be carried out at a desired pressure in the deposition chamber, with an exemplary pressure being in the range of about 1 to about 5 Torr. In more specific aspects the pressure is in the range of about 2 to about 4 Torr, or in the range of about 2.5 to about 3.5 Torr. In exemplary aspects, the chamber temperature during reducing plasma treatment is less than about 500° C., less than about 450° C., and preferably in the range of about 150° C. to about 450° C., or about 200 to about 350° C. during the Ru deposition step. In some embodiments, the chamber temperature can be in the range greater than 250° C. to about 350° C., which can have a beneficial effect of resistivity in that the formed coating can have lower resistivity.

Further, reducing plasma treatment step can be carried out at a desired period of time during the cycle, with an exemplary period being in the range of about 1 to about 30 seconds. In more specific aspects the reducing plasma treatment period is in the range of about 2 to about 25 seconds, or in the range of about 5 to about 15 seconds. In some modes of practice, the reducing plasma treatment period is longer than the Ru deposition period, such as about 1.1× to about 3× longer, or 1.5× to about 2.5× longer than the Ru deposition period.

In a fourth step of a cycle, a gas is flowed into the deposition chamber to reducing plasma/gas. The gas can be an inert gas as described herein, and conditions (flow rate, period of purge) can be within the ranges as described for the first purge (second step), or can be the same as the first purge. After a desired period of time the second purge step can end, and a new cycle of Ru deposition can begin.

The deposition cycle can be repeated a number of times as desired. For example, for ruthenium coatings having thicknesses ranging from about 1 nm to about 20 nm, coating processes using ruthenium precursors and high power reducing plasma of the disclosure can include a number of coating cycles in the range of about 10 to about 400, or more specifically about 15 to about 300.

After a desired number of deposition cycles, a post-deposition annealing step may be carried out. Annealing can be used to significantly reduce the level of impurities, e.g., carbon.

Deposition of ruthenium after a cycle, or over a desired number of cycles, can be described in one or more ways. For example, the deposition of ruthenium can be described in terms of the ruthenium deposition rate on the substrate. In modes of practice, the methods of the disclosure can provide a ruthenium deposition rate of about 0.40 Å/cycle or greater, about 0.45 Å/cycle or greater, about 0.50 Å/cycle or greater, about 0.55 Å/cycle or greater, about 0.60 Å/cycle or greater, or about 0.65 Å/cycle or greater, such as in the range of about 0.50 Å/cycle to about 0.85 Å/cycle, or about 0.55 Å/cycle to about 0.80 Å/cycle. These deposition rates can improve the overall PEALD process, as Ru films of desired thickness and quality are able to be formed on substrates using fewer deposition cycles using higher power during the reducing plasma treatment step. Ru films can be formed at these rates on substrate materials that include (a) copper (Cu), titanium (Ti), such as titanium nitride (TiN), tantalum (Ta), such as tantalum nitride (TaN), cobalt (Co), aluminum (Al), nickel (Ni), and tungsten (W), such as tungsten nitride (WN) and tungsten carbonitride (WCN), or on substrate material that includes silicon oxide (SiO₂), silicon nitride (SiN), silicon oxycarbide (SiOC), silicon oxycarbonitride (SiOCN), and silicon nitroxide (SiON).

The formed Ru films can also be described in terms of carbon content and resistivity. As a general matter, the presence of carbon in Ru films can originate from decomposed hydrocarbon ligands of ruthenium precursors. It can be desirable to minimize carbon content, among other impurities in the Ru layer, to improve properties such as electrode properties in a formed microelectronic article. Carbon content can be measured in an amount per volume of Ru coating, such as in μg of carbon per cm² of a 10 nm Ru coating (μg/cm²/10 nm Ru). For example, Ru coatings of the disclosure made using the high power reducing plasma treatment can have low carbon content, such as about less than about 1.5 μg/cm²/10 nm Ru, less than 1.25 μg/cm²/10 nm Ru, or less than 1.0 μg/cm²/10 nm Ru, less than 0.75 μg/cm²/10 nm Ru, or less than 0.60 μg/cm²/10 nm for various substrates materials useful for forming microelectronic articles (e.g., WN, WCN, SiO₂, etc.). The methods of the disclosure using high power reducing plasma treatment can reduce carbon content in Ru layers by over 20%, over 35%, and even over 50%. Likewise, the methods of the disclosure using high power reducing plasma treatment can reduce the resistivity in Ru layers by over 10%, or over 20% for dielectric substrates such as SiO₂, and even more for conductive substrates, such as WN, WCN, over 50%, 65%, or 75%.

The formed Ru films can also be described in terms of ruthenium density (expressed as a %), which can reflect the quality of the Ru film. As a general matter, the higher % the Ru density, the less micro porosity and contaminating material there is in the film, with 100% density representing a pure Ru film. Density can be calculated by measuring the film thickness using XRF and comparing this to the thickness as measured by scanning electron microscope (SEM). XRF measures theoretical film thickness (assuming 100% density). A fully dense film will have a SEM thickness equals to XRF thickness.

As deposited, a ruthenium material (e.g., ruthenium layer) may be pure or essentially pure ruthenium (e.g., at least 95, 98, 99, 99.5, or 99.9 percent (atomic) ruthenium). Low levels of impurities may be present in the ruthenium material as deposited. The impurities in the deposited ruthenium can depend largely on the composition of the precursor used, and the level of impurities in a deposited ruthenium material can be affected and desirably controlled by selected deposition conditions. Common impurities include carbon, oxygen, and nitrogen. A total amount of impurities in a ruthenium material as deposited may below about 5 atomic percent, preferably below 2, 1, or 0.5 atomic percent. If desired, as typically is, a post-deposition annealing step may be used to significantly reduce the level of impurities, e.g., carbon, to a carbon level of not greater than about 0.2 atomic percent.

The deposition chamber can include a substrate onto which a ruthenium-containing layer, such as a thin film, will form. In embodiments of the disclosure, the substrate in the deposition chamber is one that is formed into an integrated circuit (IC). The conductive feature on which the ruthenium-containing layer can form can be a conductive interconnect. Conductive interconnects such as those commonly referred to as “lines” or as “vias” are features of integrated circuit devices that provide electronic connection between other structures of the integrated circuit device. The interconnects are formed by first placing a low k dielectric material on an IC substrate, then forming openings (also referred to as “trenches” or “holes”) in the low k dielectric material that will define location, size, and shape of the lines and vias. After the openings are formed, a conductive material (e.g., copper, aluminum, tungsten, gold, silver, or an alloy thereof) is eventually deposited onto the substrate by a method that is effective to cause the conductive material to fill the openings.

A conductive material of an interconnect (i.e., an “interconnect material” or “conductive interconnect material”) may generally be any conductive material that is known at present or in the future to be useful as a conductive interconnect material; examples include aluminum, tungsten, ruthenium, molybdenum, copper, cobalt, gold, silver, cobalt, etc., as well as alloys of any one or more of these. In a preferred aspect of the disclosure, the interconnect material includes copper, or is essentially made of copper.

In embodiments, the ruthenium-containing precursor is deposited on a conductive feature to form a barrier layer or liner (sometimes referred to as a “ruthenium liner”). A ruthenium liner contacts the conductive interconnect material, and can function as a single layer barrier and liner. The ruthenium liner can separate the conductive feature from a low k dielectric material which is also part of the integrated circuit. Optionally, the integrated circuit can optionally include other barrier or liner materials, such as tantalum and tantalum nitride. The ruthenium liner can be in contact with the conductive (e.g., copper) material, the low k dielectric material, and optionally any other barrier or liner materials. The ruthenium liner can prevent any migration of conductive material of the interconnect into the low k dielectric material, which in turn prevents fouling of the integrated circuit. As an example, a thickness of a ruthenium liner may be in a range from about 0.6 to 6 nanometers, e.g., from about 1 to 3 nanometers. Preferably, the liner layer can be formed as a continuous ruthenium layer or continuous thin film.

A low k dielectric material is a dielectric material having a dielectric constant that is below about 3, e.g., below 3.0, e.g., a low k dielectric material may be considered a dielectric material that has a dielectric constant in a range from about 2.7 to about 3.0. An ultra-low k dielectric material (ULK) may be considered to be a low k dielectric material that has a dielectric constant in a range from about 2.5 to about 2.7. A dense ultra-low k dielectric material (DLK) may be considered to be a low k dielectric material that has a dielectric constant that is below about 2.5, possibly below about 2.3, for example in a range from about 2.3 to about 2.5.

Examples of each of these types of low k dielectric materials are known and available in the semiconductor and integrated circuits arts, with various examples including silicon-based low k dielectric materials and organic low k dielectric materials. Certain non-limiting examples of low k dielectric materials include materials known in the semiconductor and integrated circuit arts as: carbon-doped silicon oxides, fluorine-doped silicon oxides, a hydrogen-enriched silicon oxycarbide (SiCOH); porous silicon oxides, porous carbon-doped silicon oxides, porous SiLK™, spin-on silicone based polymeric dielectrics such as methyl silsesquioxane (MSQ) and hydrogen silsesquioxane (HSQ), and spin-on organic polymeric dielectrics.

In other embodiments the ruthenium-containing precursor can be used to form a ruthenium-containing layer in association with a device that is different than an integrated circuit, such as one that is different and used with a semiconductor-containing device, or that is part of a, flat panel or LCD device, or that is a photovoltaic device. Such devices can include materials such as silicon-containing materials such as silica, silicon nitride, carbon doped silica, silicon oxy nitride, and/or conductive materials such as copper, and copper alloys, or noble metals such as gold, platinum, palladium, and rhodium. Materials such as titanium nitride, tantalum, tantalum nitride, and tungsten may be included in such devices. Substrates that the ruthenium-containing layer can be formed can include layers or architectures that contain any of these materials.

Optionally, the methods of the disclosure which include forming a ruthenium-containing layer on a substrate may further include other integrated circuit formation processes. For example, additional further processing steps can include forming or treating dielectric material. For example, additional processing steps can involve forming openings in the low k dielectric material. Various conventional methods of placing openings in low k dielectric materials are known. The openings, which may be a “trench” or a “hole,” may be formed, for example, by use of photoresist and etching processes by which photoresist material is applied to the surface of the low k dielectric material and developed to provide selectivity of locations to be removed or left behind during a subsequent etching step. The photoresist is selectively removed and the openings are formed by the etching step, which can be performed by use of any present or future useful methods and materials. Remaining photoresist can be removed by a “post-etch” cleaning or treatment step by which one or more of a liquid, solvent, surfactant, or plasma, with optional mechanical treatment (e.g., brushes) can be used to remove the remaining photoresist. Some amount of residual photoresist material may still remain at surfaces of the low k dielectric layer, including at the openings, as well as other possible contamination.

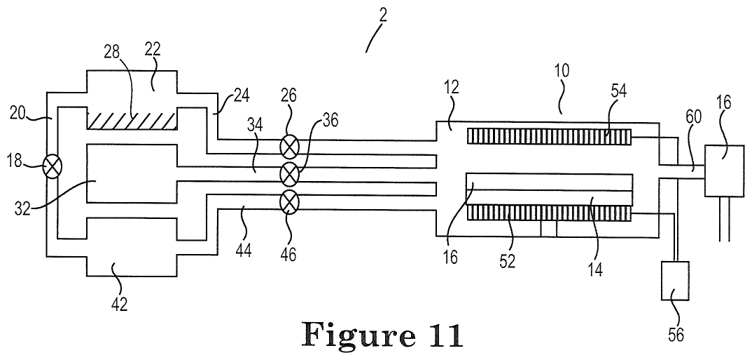

Deposition of ruthenium from a ruthenium-containing precursor of the disclosure can be performed using available PEALD equipment and generally understood techniques, adapted for use to deposit ruthenium using a ruthenium containing precursor in a PEALD process using reducing plasm as described herein. As a single example of a useful system for a method of the present description, FIG. 11 schematically shows a system that can be useful for carrying out a PEALD process as described. Illustrated is a PEALD system 2, including deposition chamber 10 having interior 12 which contains platen 14, which supports substrate 16. Interior 12 as illustrated is sized to accommodate a single substrate 16, but may be of any size, to contain multiple substrates for PEALD processing. The deposition chamber also include a plasma generating system that includes anode 52, cathode 54, which are connected to RF power source 52, which is capable of generating powers greater than 200 W (such as powers in the range of about 250 to about 500 W) to generate reducing plasma when reducing gas is introduced into the chamber 10.

The system can include “flow circuitry” which can include a series of conduits and valves, or other delivery and control mechanisms for delivery of deposition reagents (ruthenium precursor, reducing gas, inert gas) from their respective sources to the deposition chamber. The flow of deposition reagents can be manually or electronically controlled to provide desired amounts of the deposition reagents to the deposition chamber.

Still referring to FIG. 11, ruthenium precursor 28 (e.g., in liquid form) is present in a container 22, such an ampoule, wherein the container 22 has an interior with a volume of a size sufficient to contain a desired amount of ruthenium precursor 28 and an amount of additional volume or “headspace,” including space above the liquid or solid precursor. Carrier gas source 42 is a source of carrier gas, such as an inert gas like argon. Reducing gas source 32 is a source of reducing gas such as ammonia, hydrogen, or mixtures thereof. Conduit 20 (e.g., tubing) connects carrier/inert gas source 18 to container 22, and the flow of inert gas can be regulated by valve 18. Conduit 24 connects container 22 to the interior 12 of deposition chamber 10. In use, carrier gas from carrier gas source 18 can flow through conduit 20 to container 22 where an amount of ruthenium-containing precursor 28, in vapor form, is introduced into the carrier gas. From container 22, the carrier gas carries the precursor 28 vapor (as a carrier gas-precursor mixture) through conduit 24, through valve 26, and into interior 12.

Optionally, precursor 28, present in container 22, can be dissolved in a solvent, e.g., an organic solvent. Various examples of solvents for use with PEALD precursors are known, with particular examples including hydrocarbon compounds (including, alkanes, alcohols, ketones, etc.) such as octane, nonane, decane, and ethers such as tetrahydrofuran.

Conduit 34 connects reducing gas (e.g., ammonia, hydrogen) source 32 to interior 12 of deposition chamber 10. In use, reducing gas from reducing gas source 32 can flow through conduit 34, through valve 36, and into interior 12. In a system such as that of Figure X, or an alternate system that is also effective for plasma enhanced atomic layer deposition of the ruthenium-containing precursor as described, deposition processing parameters can be controlled to provide desired properties of a processed substrate.

Conduit 44 connects inert gas source 42 to interior 12 of deposition chamber 10. In use, inert gas such as argon from inert gas source 42 can flow through conduit 44, through valve 46, and into interior 12. Alternatively, the inert gas conduit can lead into the reducing gas conduit or the precursor conduit (not shown), or both, which can provide mixing of these reagents prior to entering the deposition chamber.

The deposition apparatus or deposition chamber can also be configured with a port 60 or outlet to allow removal of products from the chamber. The port or outlet can be in gaseous communication with (e.g., connected to) a vacuum pump 62 to allow by products to be removed from the chamber. Pressure within the reaction chamber can also be modulated using the port or outlet.

### Example 1

PEALD Deposition of P-Cymene(1,3-Cyclohexadiene)Ru with 26% NH₃ Pulse at 400 W Plasma Power (5-5-10-5).

P-Cymene(1,3-Cyclohexadiene)Ru (P-cymene CHD Ru), as described in Eom, T.-K., et al. (Electrochemical and Solid State Letters, 12:D85-D88, 2009) was used.

Cu, TaN, TiN, WCN, WN, and SiO₂ were used as substrates for Ru deposition.

The following PEALD deposition cycle was used: 5 second Ru precursor pulse; 5 second argon purge; 10 second ammonia (NH₃) plasma pulse; 5 second argon purge (5-5-10-5).

Temperature in the deposition chamber was 250° C. and a pressure of 3 Torr was used.

For Ru precursor delivery, an argon carrier flow rate of 335 sccm and a ProE-Vap temperature of 100° C. were used.

Throughout the cycle argon was flowed into the chamber at 610 sccm.

Table 1 details Ru deposition rate (Å/cycle) on coated substrates.

TABLE 1

| Substrate | Incubation Cycle | Dep Rate (Å/cycle) |
|---|---|---|
| TaN | 5 | 0.71 |
| TiN | 4 | 0.70 |
| WN | 3 | 0.68 |
| WCN | 3 | 0.67 |
| SiO₂ | 35 | 0.72 |
| Cu | 0 | 0.69 |

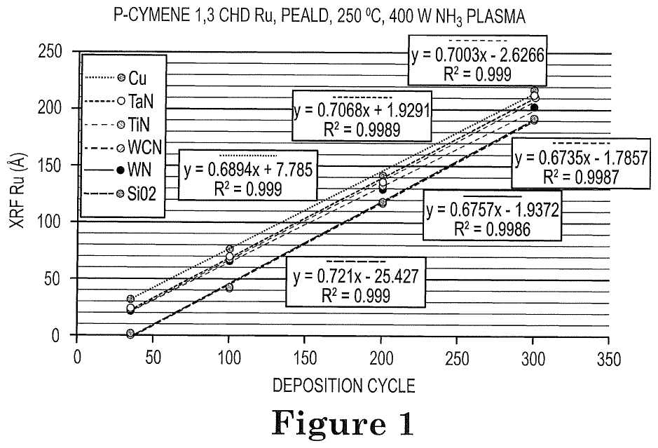

FIG. 1A is a graph showing increases in Ru coating thickness (Å) as measured by X ray fluorescence spectroscopy (XRF) on Cu, TaN, TiN, WCN, WN, and SiO₂ after numbers of deposition cycles.

FIGS. 1B and 1C are SEM images showing Ru coatings formed on trenched substrates, demonstrating ˜96% conformality on 35 nm size trench (AR ˜3), and ˜70% conformality on 16 nm size trench side wall (AR ˜6).

### Example 2

PEALD Deposition of P-Cymene(1,3-Cyclohexadiene)Ru with 26% NH₃ Pulse at 400 W Plasma Power (8-5-10-5).

PEALD deposition was carried out according to Example 1, but using an 8 second pulse instead of a 5 second pulse.

Table 2 details Ru deposition rate (Å/cycle) on coated substrates.

TABLE 2

| Substrate | Incubation Cycle | Dep Rate (Å/cycle) |
|---|---|---|
| TaN | 7 | 0.72 |
| TiN | 6 | 0.71 |
| WN | 1 | 0.71 |
| WCN | 5 | 0.68 |
| SiO₂ | 25 | 0.72 |
| Cu | 0 | 0.74 |

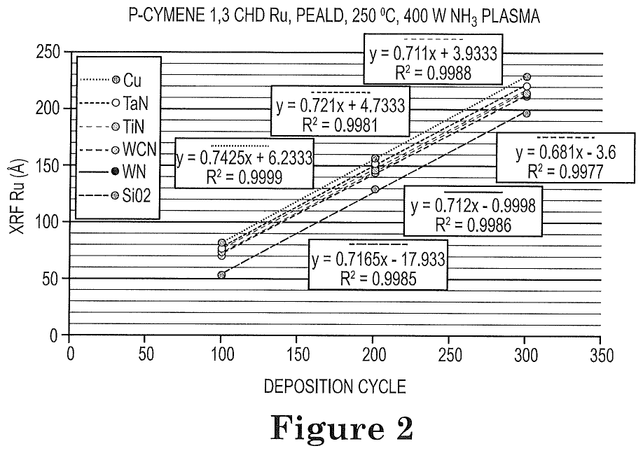

FIG. 2 is a graph showing increases in Ru coating thickness (Å) as measured by X ray fluorescence spectroscopy (XRF) on Cu, TaN, TiN, WCN, WN, and SiO₂ after numbers of deposition cycles.

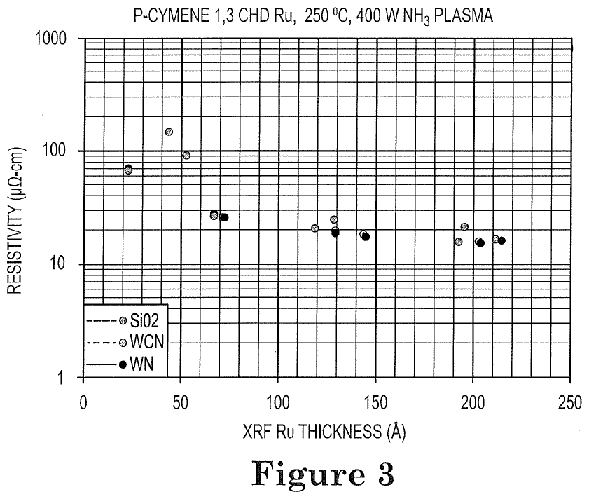

FIG. 3 is a graph showing resistivity of Ru coating based on thickness (Å) on WCN, WN, and SiO₂ substrates, demonstrating low electrical resistivity at Ru thickness<5 nm on WCN/WN.

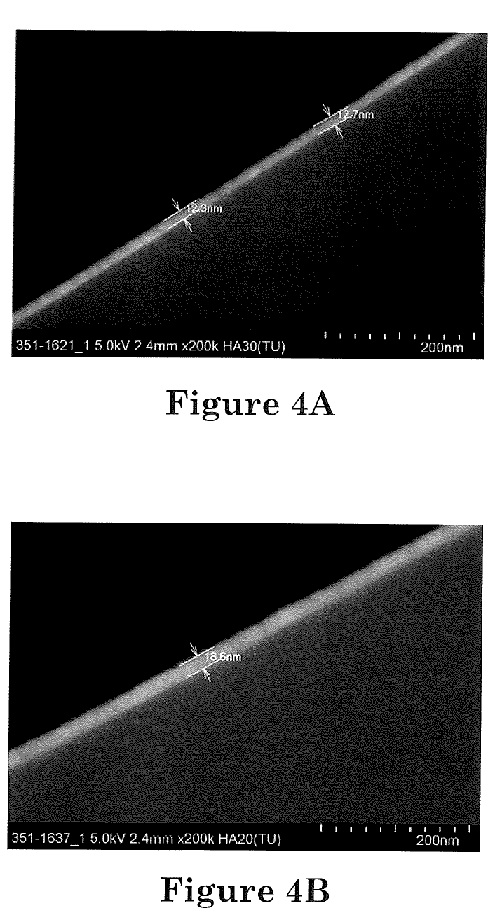

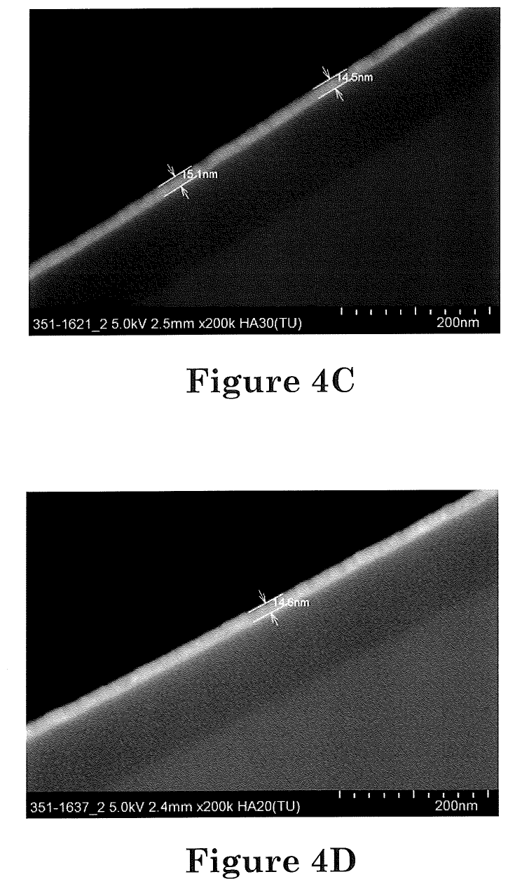

FIG. 4A is a scanning electron micrograph (SEM) image of a dense as dep Ru coating on SiO₂ formed using higher power Ru deposition process.

FIG. 4B is a scanning electron micrograph (SEM) image of a dense as dep RTH annealed Ru coating on SiO₂ formed using higher power Ru deposition process.

FIG. 4C is a scanning electron micrograph (SEM) image of a dense as dep Ru coating on WCN formed using higher power Ru deposition process.

FIG. 4D is a scanning electron micrograph (SEM) image of a dense as dep RTH annealed Ru coating on WCN formed using higher power Ru deposition process.

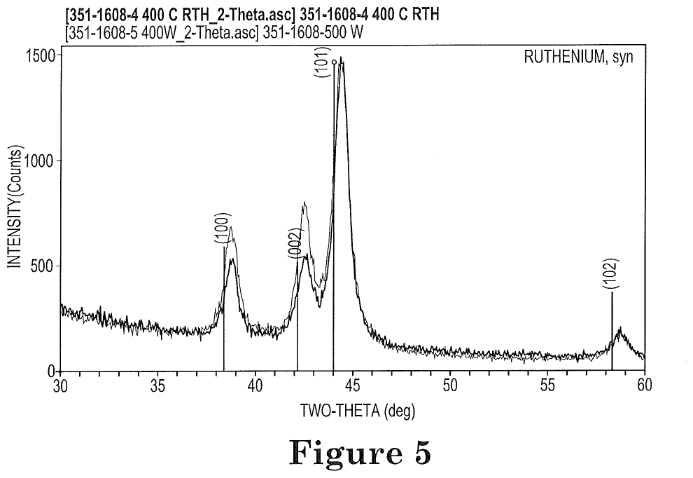

FIG. 5 is an X-ray diffraction (XRD) graph of a Ru coating, as-dep and post 400° C. RTH anneal.

### Example 3

PEALD Deposition of P-Cymene(1,3-Cyclohexadiene)Ru with H₂ Plasma Pulse at 250° C. Using 400 W Plasma Power (5-5-10-5).

PEALD deposition was carried out according to Example 1, but using 26% H₂ as the reducing plasma.

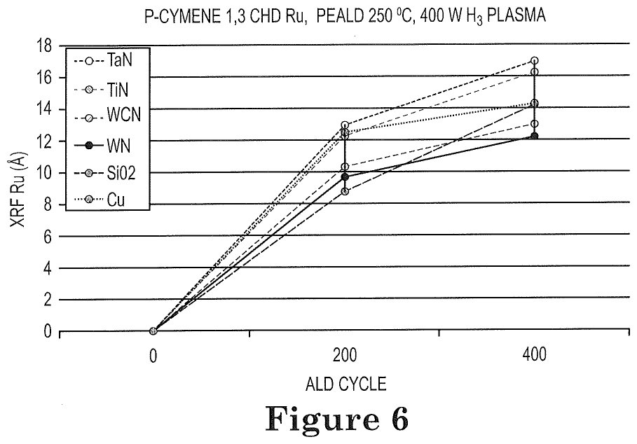

FIG. 6 is a graph showing increases in Ru coating thickness (Å) as measured by X ray fluorescence spectroscopy (XRF) on Cu, TaN, TiN, WCN, WN, and SiO₂ after numbers of deposition cycles.

Comparative studies were also performed using no power (0 W) with NH₃ and H₂ gasses to determine coating thickness (Å) over 200 deposition cycles and compared to coatings made using higher powers; results are shown in Table 3.

TABLE 3

| | 400 W | 200 W | 0 W | 400 W | 0 W |
|---|---|---|---|---|---|
| Substrate | NH3 | NH3 | NH3 | H2 | H2 |
| TaN | 135.5 | 73.8 | 0.8 | 12.9 | 0.9 |
| TiN | 132.1 | 72.9 | 1.7 | 12.3 | 1.8 |
| WN | 128.9 | 72.0 | 4.5 | 9.7 | 4.9 |
| WCN | 128.8 | 54.0 | 3.9 | 10.4 | 4.6 |
| SiO₂ | 118.1 | 72.1 | 0.1 | 8.8 | 0.1 |
| Cu | 142.1 | 82.9 | 2.4 | 12.5 | 2.3 |

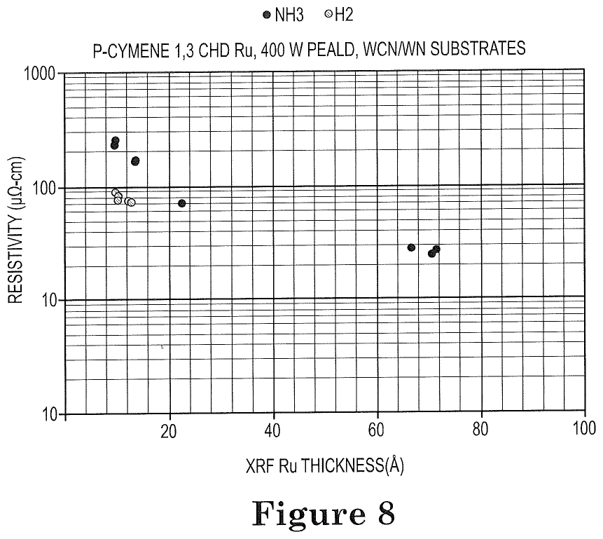

Ru films deposited on WCN/WN with H₂ plasma have lower resistivity then those deposited with NH₃ plasma, as shown in FIG. 8.

### Example 4

PEALD Deposition of P-Cymene(1,3-Cyclohexadiene)Ru with H₂ Plasma Pulse at 400 W and 280° C.

PEALD deposition was carried out according to Example 3, but at 280° C. instead of 250° C.

Increasing deposition temperature to 280° C. did not significantly increase Ru DR, but reduced Ru resistivity; results are shown in Table 4.

TABLE 4

| | XRF Ru Thickness (Å) | | As-dep Resistivity (μΩ-cm) | |
|---|---|---|---|---|
| Substrate | 250° C. | 280° C. | 250° C. | 280° C. |
| TaN | 12.9 | 13.4 | — | — |
| TiN | 12.3 | 12.5 | — | — |
| WN | 9.7 | 10.2 | 90.5 | 79.0 |
| WCN | 10.4 | 10.1 | 81.0 | 74.3 |
| SiO₂ | 8.8 | 8.7 | 509,625 | 89,366 |
| Cu | 12.5 | 11.3 | — | — |

SEM results also showed better Ru nucleation and lower resistivity on SiO₂ substrate with 280° C. deposition

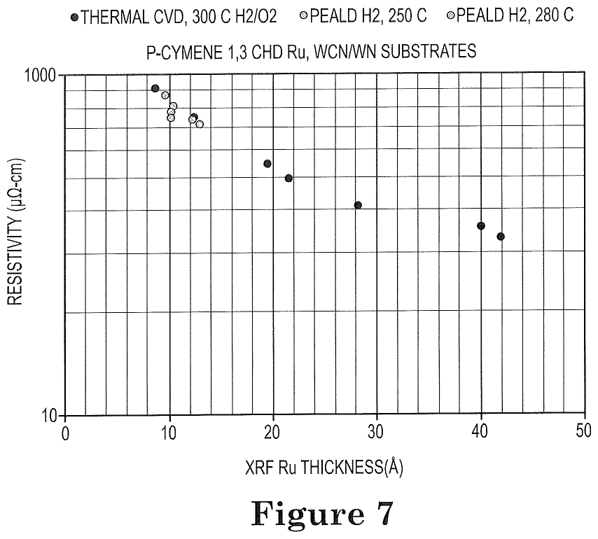

Ru thin films deposited at 280° C. with H₂ PEALD have lower resistivity than those deposited with 02 thermal CVD. See FIG. 7.

### Example 5 (Comparative)

PEALD Deposition of P-Cymene(1,3-Cyclohexadiene)Ru with NH₃ Plasma Pulse at 200 W (5-5-10-5).

PEALD deposition was carried out according to Example 1, but using 200 W as reducing plasma power.

Table 5 details Ru deposition rate (Å/cycle) on coated substrates.

TABLE 5

| Substrate | Incubation Cycle | Dep Rate (Å/cycle) |
|---|---|---|
| TaN | 39 | 0.44 |
| TiN | 37 | 0.43 |
| WN | 37 | 0.43 |
| WCN | 42 | 0.44 |
| SiO₂ | 68 | 0.41 |
| Cu | 13 | 0.43 |

Table 6 details resistivity and carbon content on coated substrates.

TABLE 6

| | | | | | C/Ru |
|---|---|---|---|---|---|
| | Plasma Power | | XRF Ru | Resistivity | (μg/cm²/ |
| Substrate | (W) | Cycle | (Å) | (μΩ-cm) | 10 nm Ru) |
| WN | 200 | 200 | 72.0 | 115 | 1.71 |
| SiO2 | 200 | 200 | 54.0 | 199.7 | 1.25 |
| WCN | 200 | 200 | 72.1 | 114.7 | 1.85 |

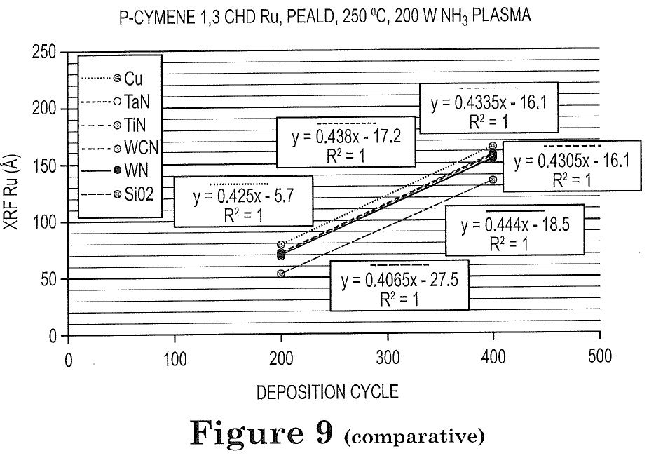

FIG. 9 is a graph showing increases in Ru coating thickness (Å) as measured by X ray fluorescence spectroscopy (XRF) on Cu, TaN, TiN, WCN, WN, and SiO₂ after numbers of deposition cycles.

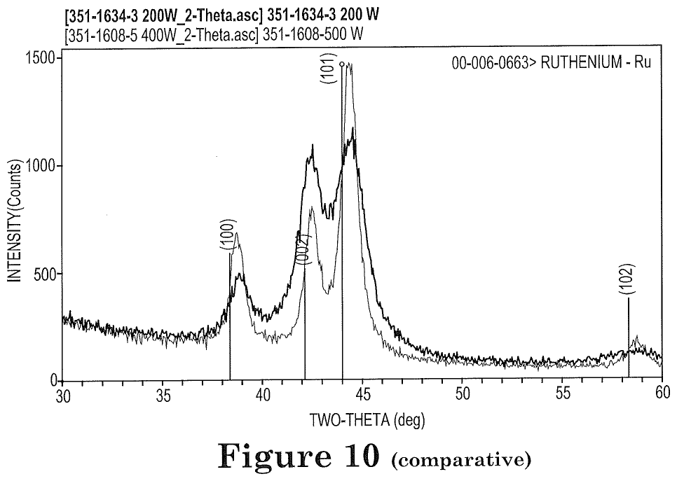

FIG. 10 is a graph showing broader XRD peaks with 200 W NH₃ plasma.

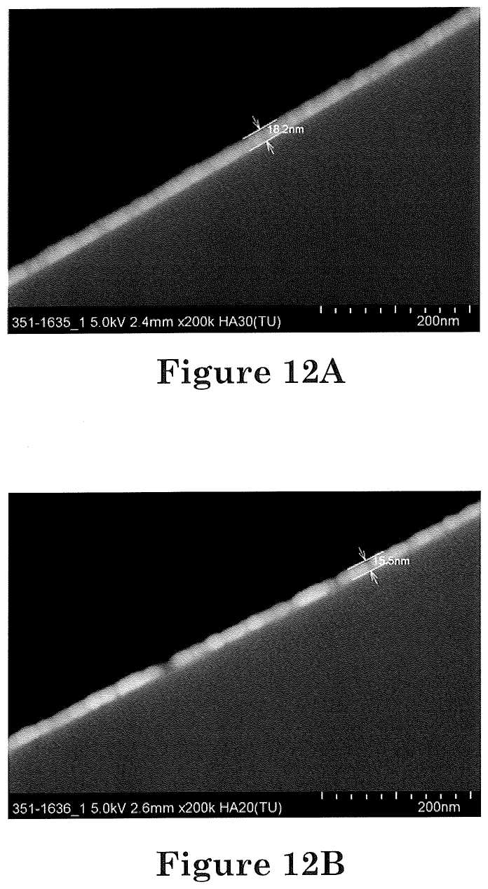

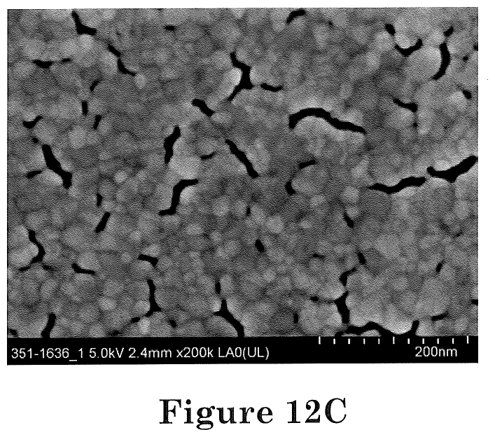

FIG. 12A is a scanning electron micrograph (SEM) image of a porous as-dep Ru coating on SiO₂ formed using 200 W Ru deposition process.

FIG. 12B is a scanning electron micrograph (SEM) image of a porous RTH annealed Ru coating on SiO₂ formed using 200 W Ru deposition process.

FIG. 12C is a scanning electron micrograph (SEM) top-down image of a porous RTH annealed Ru coating on SiO₂ formed using 200 W Ru deposition process showing severe cracks of the Ru film due to shrinkage from annealing.

What is claimed is:

1. A method for depositing ruthenium comprising:
(a) providing a ruthenium precursor of the Formula I: R^{A}R^{B}Ru(0), wherein R^{A} is an aryl group-containing ligand, and R^{B} is a diene group-containing ligand, to a substrate surface; and
(b) providing a reducing plasma to the substrate surface using a power of greater than 200 W,
wherein ruthenium is deposited on the substrate in a plasma enhanced atomic layer deposition (PEALD) process.

2. The method of claim 1 wherein the ruthenium-containing precursors is of Formula II: 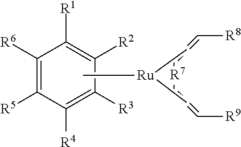
wherein one or more or R¹-R⁶ are selected from H and C1-C6 alkyl, R⁷ is 0 (covalent bond) or a divalent alkene group of 1-4 carbon atoms, and R⁸ and R⁹ form one or more ring structures or are selected from H and C1-C6 alkyl.

3. The method of claim 2 wherein one, two, or three of R¹-R⁶ are selected from C1-C3 alkyl, with the remaining R¹-R⁶ being H.

4. The method of claim 2 wherein R⁷ is 0 (covalent bond), and R⁸ and R⁹ form one or more ring structures.

5. The method of claim 1 wherein R^{A} and R^{B} do not include any heteroatoms.

6. The method of claim 1 wherein the ruthenium precursor has a total carbon atom amount in the range of 12 to 20, 14 to 18, or 15 to 17.

7. The method of claim 1 wherein the ruthenium precursor has a total hydrogen atom amount in the range of 16 to 28, in the range of 19 to 25, or in the range of 20-24.

8. The method of claim 1 wherein R^{A} is a di-alkylbenzene having two different alkyl groups.

9. The method of claim 1 wherein R^{A} is selected from the group consisting of toluene, xylene, ethylbenzene, cumene, and cymene.

10. The method of claim 1 wherein R^{B} is a cyclic diene.

11. The method of claim 1 wherein R^{B} is a conjugated diene.

12. The method of claim 1 wherein R^{B} is 1,3- or 1,4-cyclohexadiene or an alkylcyclohexadiene.

13. The method of claim 1 wherein ruthenium precursor is selected from the group consisting of (cymene)(1,3-cyclohexadiene)Ru(0), (cymene)(1,4-cyclohexadiene)Ru(0), (cymene)(1-methylcyclohexa-1,3-diene)Ru(0), (cymene)(2-methylcyclohexa-1,3-diene)Ru(0), (cymene)(3-methylcyclohexa-1,3-diene)Ru(0), (cymene)(4-methylcyclohexa-1,3-diene)Ru(0), (cymene)(5-methylcyclohexa-1,3-diene)Ru(0), (cymene)(6-methylcyclohexa-1,3-diene)Ru(0), (cymene)(1-methylcyclohexa-1,4-diene)Ru(0), (cymene)(2-methylcyclohexa-1,4-diene)Ru(0), (cymene)(3-methylcyclohexa-1,4-diene)Ru(0), (cymene)(4-methylcyclohexa-1,4-diene)Ru(0), (cymene)(5-methylcyclohexa-1,4-diene)Ru(0), and (cymene)(6-methylcyclohexa-1,4-diene)Ru(0).

14. The method of claim 1 wherein the ruthenium precursor is selected from the group consisting of (benzene)(1,3-cyclohexadiene)Ru(0), (toluene)(1,3-cyclohexadiene)Ru(0), (ethylbenzene)(1,3-cyclohexadiene)Ru(0), (1,2-xylene)(1,3-cyclohexadiene)Ru(0), (1,3-xylene)(1,3-cyclohexadiene)Ru(0), (1,4-xylene)(1,3-cyclohexadiene)Ru(0), (p-cymene)(1,3-cyclohexadiene)Ru(0), (o-cymene)(1,3-cyclohexadiene)Ru(0), (m-cymene)(1,3-cyclohexadiene)Ru(0), (cumene)(1,3-cyclohexadiene)Ru(0), (n-propylbenzene)(1,3-cyclohexadiene)Ru(0), (m-ethyltoluene)(1,3-cyclohexadiene)Ru(0), (p-ethyltoluene)(1,3-cyclohexadiene)Ru(0), (o-ethyltoluene)(1,3-cyclohexadiene)Ru(0), (1,3,5-trimethylbenzene)(1,3-cyclohexadiene)Ru(0), (1,2,3-trimethylbenzene)(1,3-cyclohexadiene)Ru(0), (tert-butylbenzene)(1,3-cyclohexadiene)Ru(0), (isobutylbenzene)(1,3-cyclohexadiene)Ru(0), (sec-butylbenzene)(1,3-cyclohexadiene)Ru(0), (indane)(1,3-cyclohexadiene)Ru(0), (1,2-diethylbenzene)(1,3-cyclohexadiene)Ru(0), (1,3-diethylbenzene)(1,3-cyclohexadiene)Ru(0), (1,4-diethylbenzene)(1,3-cyclohexadiene)Ru(0), (1-methyl-4-propylbenzene)(1,3-cyclohexadiene)Ru(0), and (1,4-dimethyl-2-ethylbenzene)(1,3-cyclohexadiene)Ru(0).

15. The method of claim 1 wherein, in step (a) the ruthenium precursor is provided in a gas stream flow comprising an inert gas selected from helium, argon, krypton, neon, and xenon.

16. The method of claim 1 wherein step (a), the ruthenium precursor is provided in a gas stream flow at a flow rate in the range of 250-425 sccm, in the range of 300-375 sccm, or in the range of 320-350 sccm.

17. The method of claim 1 wherein in step (a), the ruthenium precursor is provided at a temperature of not greater than 125° C., or in the range of 80-120° C.

18. The method of claim 1 wherein in step (a), the ruthenium precursor is provided at a process pressure in the range of 1-5 Torr, in the range of 2-4 Torr, or in the range of 2.5-3.5 Torr.

19. The method of claim 1 wherein the reducing plasma comprises hydrogen H₂ (hydrogen), NH₃ (ammonia), or a mixture thereof.

20. A plasma enhanced atomic layer deposition (PEALD) system:
a ruthenium source comprising a ruthenium precursor of the formula R^{A}R^{B}Ru(0), wherein R^{A} is an aryl group-containing ligand, and R^{B} is a diene group-containing ligand; and
a plasma supply source capable of providing a reducing plasma; and
a power source capable of providing power to the plasma of greater than 200 W.
